(19) United States
(12) Patent Application Publication
(10) Pub. No.: US 2010/0219469 A1
(43) Pub. Date: Sep. 2, 2010

(54) MASK ROM CELL STRUCTURE AND METHOD OF FABRICATING THE SAME

(75) Inventors: Hong-Kook Min, Yongin-si (KR); Yong-Suk Choi, Hwaseong-si (KR); Sung-Kyoo Park, Bucheon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/712,400

(22) Filed: Feb. 25, 2010

(30) Foreign Application Priority Data
Feb. 27, 2009 (KR) 10-2009-0017170

(51) Int. Cl. H01L 29/78; H01L 21/336

(52) U.S. Cl. 257/330; 438/270; 257/E21.41; 257/E29.262

(57) ABSTRACT

A mask read-only memory (ROM) cell structure includes buried gate electrodes, common source regions under the gate electrodes, common drain regions extending between upper portions of adjacent ones of the gate electrodes, and two vertical channel regions on opposite sides, respectively, of each of the gate electrodes. The channel regions are selectively coded such that the cell transistors are on or off depending on whether the channel region of the transistor is coded. To this end, selected ones of the channel regions of the mask ROM structure are coded by forming ion implantation regions that differentiate the threshold voltages of the thus coded channel regions from the non-coded channel regions. The coding process may thus be carried out using a shallow ion implantation process. Accordingly, a relatively thin mask for coding may be used, and the ion implantation process may be carried out at a relatively low energy level.

### PRIORITY STATEMENT

This application claims the benefit of priority under 35 U.S.C. §119 from Korean Patent Application No. 10-2009-0017170, filed on Feb. 27, 2009.

### BACKGROUND

1. Field

The inventive concept relates to memory cells of semiconductor devices and to methods of fabricating the same. More particularly, the inventive concept relates to mask ROM (read-only memory) devices and to methods of fabricating mask ROM devices.

2. Description of Related Art

Among semiconductor devices, a mask ROM device is a non-volatile memory, meaning that stored data are retained even when the power supplied to the device is interrupted. In addition, a mask ROM device is only readable, not writable. In this respect, the transistors of a mask ROM device are MOS transistors.

Recently, mask ROMs have been increasingly used in smart cards and mobile devices. A smart card, for example, may serve as a credit card or electronic cash. In this respect, the smart card stores various pieces of information about a user and transactions, and has built-in programs suitable to process such information. Thus, the smart card includes non-volatile memory transistors configured to write/store various pieces of information about a user and transactions, and mask ROM transistors storing hard code.

The mask ROM transistors of the type found in smart cards mainly consist of a combination of depletion-type and enhancement-type transistors. The channel, source and drain regions of these transistors have a planar layout. Thus, it is difficult to increase the degree of integration of a mask ROM cell without giving rise to short channel effects. Furthermore, the channel regions of the transistors are formed under gate electrodes, and selected ones of the channel regions are coded after the gate electrodes are formed. The coding is carried out by an ion implantation process using a mask that exposes the channel regions to be coded. Therefore, the lattice structure of a gate electrode can be damaged due to the high level of energy that passes through the gate electrode during the implanting of ions into the underlying channel region. Further still, it is difficult to form a fine pattern of coded channel regions due to the fact that the photoresist pattern which masks the substrate during the coding process must be rather thick to prevent the implantation of ions into parts of the active region other than the channel regions to be coded.

### SUMMARY

According to one aspect of the inventive concept, there is provided a method of fabricating a mask ROM cell structure by which channel regions of the transistors may be coded using shallow ion implantation. An active region of a semiconductor substrate is etched at regular intervals to form trenches in the active region of the semiconductor substrate. Common source regions are formed along the bottoms of the trenches by implanting impurity ions into surfaces of the substrate which delimit the bottoms of the trenches. A gate oxide layer is formed along the bottom and sides of each of the trenches. The trenches are then overfilled with gate electrode material, and the gate electrode material is planarized to form gate electrodes in the trenches, respectively. Common drain regions are formed along upper portions of the segments of the active region that separate the trenches from each other, respectively, and channel regions which extend to the common source regions are formed vertically along the sides of the segments. The common drain regions and the channel regions are formed by implanting impurity ions into the active region of the substrate. Also, a coding process is performed to selectively code the channels. The coding process results in the threshold voltages of at least one of the channel regions is differentiated from the threshold voltage of at least one other of the channel regions.

According to another aspect of the inventive concept, there is provided a mask ROM cell structure having a high density of coded transistors. The structure includes a semiconductor substrate having an active region and trenches in the active region, gate electrodes buried in the trenches, respectively, common source regions under the gate electrodes, respectively, common drain regions each extending between and connecting upper portions of adjacent ones of the gate electrodes, and vertical channel regions extending along the sides of the gate electrodes, respectively. Thus, two vertical channel regions respectively extend along the sides of each of the gate electrodes, and each of the vertical channel regions extends vertically between a respective one of the common source regions and a respective one of the common drain regions. The channel regions are selectively coded such that at least one of the channel regions has a threshold voltage that is different from that of at least one other of the channel regions.

### BRIEF DESCRIPTION OF THE DRAWINGS

The inventive concept and the advantages thereof will be better understood from the description that follows made with reference to the accompanying drawings.

FIG. 1 is a cross-sectional view of a mask read-only memory (ROM) cell.

FIGS. 2 and 3 are each a cross-sectional view of a substrate illustrating a method of fabricating the mask ROM cell shown in FIG. 1, wherein FIG. 1 illustrates an initial stage in which gate electrodes are formed, and FIG. 3 illustrates a subsequent selective ion implantation process for data coding.

FIG. 4 is a plan view of a mask ROM device including a mask ROM cell structure according to the inventive concept.

FIG. 5 is a cross-sectional view taken along line I-I of FIG. 4.

FIG. 6 is a table of operations of the mask ROM cell device of FIGS. 4 and 5.

FIGS. 7-15 are each a cross-sectional view of a substrate and together illustrate an embodiment of a method of fabricating a mask ROM cell according to the inventive concept.

### DETAILED DESCRIPTION OF THE PREFERRED EMBODIMENTS

Preferred embodiments of the inventive concept will now be described more fully with reference to the accompanying drawings. Like reference numbers designate like elements throughout the drawings. Also, in the drawings, the thicknesses of layers and regions may be exaggerated for clarity. In particular, the cross-sectional illustrations of a mask ROM cell and intermediate structures fabricated during the course of its manufacture are schematic. Thus, mask ROM cells according to the inventive concept are not to be construed as limited by the particular shapes and relative sizes of elements and regions of the mask ROM cell illustrated herein; rather, the particular shapes and relative sizes of such elements and regions may in practice deviate from those illustrated due, for example, to manufacturing techniques and tolerances. For example, an implanted region illustrated as rectangular may in actuality have rounded or curved edges and/or a gradient (e.g., a varying concentration of ions) rather than exhibiting an abrupt change at an interface with a non-implanted region.

Furthermore, spatially relative terms, such as “beneath,” “below,” “lower,” “above,” “upper” and the like are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use.

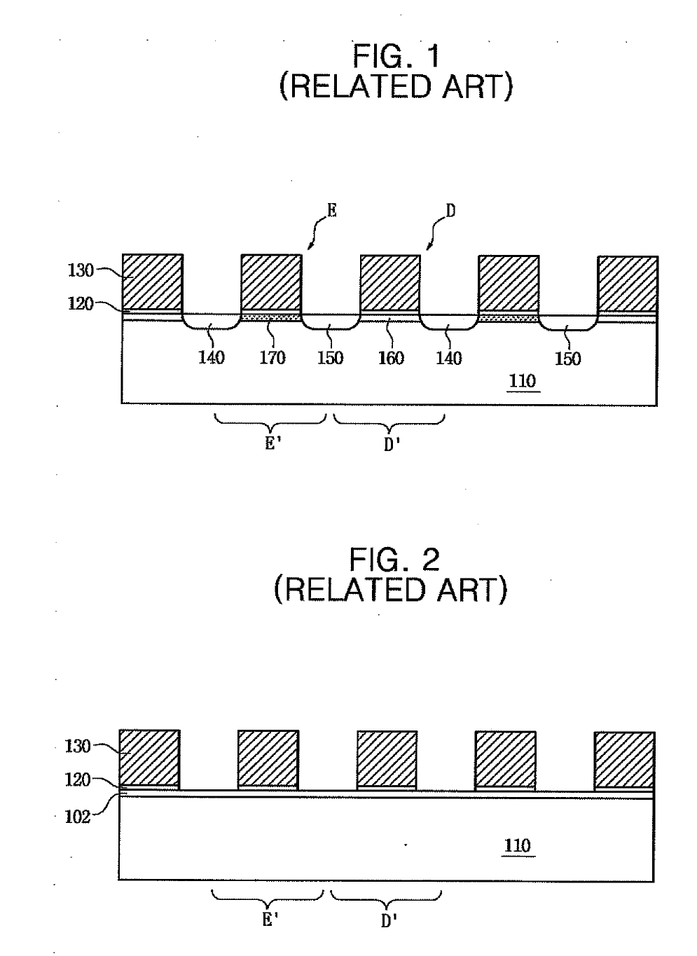

A basic mask ROM cell structure and the operation thereof will now be described with reference to FIG. 1. The mask ROM cell structure includes a depletion-type cell transistor D and an enhancement-type cell transistor E. The transistors D and E are NMOS transistors in this example. Thus, each transistor includes a gate oxide layer 120 on a p-type semiconductor substrate 110, a gate electrode 130 on the gate oxide layer 120, and n-type source and drain regions 140 and 150 in the semiconductor substrate 110 on opposite sides, respectively, of the gate electrode 130.

The depletion-type transistor D has a first channel region 160 doped with an n-type impurity. Therefore, even when a voltage is not applied to the gate electrode 130 of the transistor D, the transistor D is in an ON state due to the depletion-type channel. Conversely, the enhancement-type transistor E has a second channel region 170 doped with a p-type impurity. Therefore, when a voltage is not applied to the gate electrode 130 of the transistor E, the transistor E is in an OFF state. The transistors D and E store code of “1” or “0” depending on whether the transistor is ON or OFF. The states of the transistors may be discerned and accordingly, data in the form of “1” or “0” can be read out from each transistor.

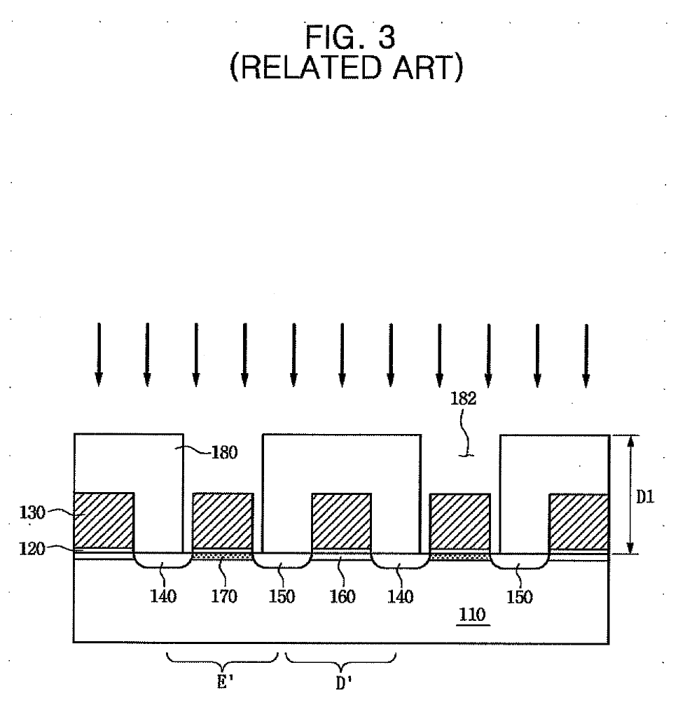

A method of fabricating the mask ROM cell structure, including the coding of cells of the same, will now be described with reference to FIGS. 2 and 3.

First, active regions are defined by forming an isolation layer (not shown) in the semiconductor substrate 110 having first and second regions D′ or E′. A surface doping layer 102 is formed by implanting n-type impurity ions into a surface of an active region. The surface doping layer 102 will form a channel region of each transistor.

A plurality of gate oxide layers 120 and gate electrodes 130 are sequentially formed on the active region. The n-type source and drain regions 140 and 150 are formed by implanting n-type impurity ions into the substrate 110 using the gate electrodes 130 as a mask. Thus, each gate electrode 130, the channel region under the gate electrode 130, and the source and drain regions 140 and 150 on opposite sides of the gate electrode 130 constitute a unit cell of the mask ROM.

Subsequently, as shown in FIG. 3, respective ones of the channel regions are coded by an after gate programming (AGP) process. More specifically, an ion-implantation photoresist (IIP) is formed on the semiconductor substrate 110, and is patterned. The resulting photoresist pattern 180 has openings 182 that expose respective ones of the cells selected to produce a product that will meet the demands of an end user. As an example, a cell in the second region E′ is selected, and thus the gate electrode 130 in the second region E′ is exposed by the opening 182. If necessary, portions of the source and drain regions 140 and 150 of the selected cell may also be exposed by the opening 182. The channel region of each selected cell is doped with p-type impurity ions, e.g. boron, by ion implantation using the photoresist pattern 180 as a mask.

However, the above-described mask ROM cell structure and the method of coding the same have the following technical disadvantages.

First, the mask ROM cell is of a planar type. Therefore, it is difficult to produce a highly integrate mask ROM device made up of the mask ROM cells. More specifically, the gate electrode 130 and the source and drain regions 140 and 150 are disposed along a line such that the channel, source and drain regions are essentially coplanar. Thus, the footprint of the mask ROM cell is relatively large. Attempts to minimize the footprint may give rise to a short channel effect, including a drain-induced barrier lowering (DIBL) effect in which a depletion layer of a drain interacts with a source-channel junction to lower a potential barrier of the source junction.

The uniformity of the cell structures, i.e., between the unit cells which have been programmed and those which have not, is reduced by the ion implantation process.

As mentioned above, the programming of the enhancement-type cell transistor E uses an ion-implantation photoresist (IIP). In this respect, high ion-implantation energy is required to propel the p-type impurity ions through the gate electrode 130. Accordingly, the thickness (D1 in the figure) of the IIP must be relatively great to prevent the implantation of ions into the channel regions 160 of the depletion-type cell transistors D, for example. However, the resolution of the photolithography process used to pattern the IIP is limited by the thickness of the IIP.

Furthermore, high ion-implantation energy applied to the gate electrode 130 of the selected cell may damage the lattice structure of the gate electrode 130. In addition, an interface between the gate electrode 130 and the gate oxide layer 120 may be damaged. In this case, the selected cell may exhibit excessive leakage current. Moreover, the p-type impurity ions are implanted into the source and drain regions 140 and 150 of the selected cell in a Gaussian distribution. Therefore, a so-called punch-through phenomenon may occur between the source and drain regions 140 and 150.

Alternatively, the selective ion implantation process may be performed before the gate electrodes 130 are formed (before gate programming: BGP) to prevent the gate electrodes 130 of the selected cells from being damaged. According to the BGP method, the program coding, the forming of the gate electrodes 130, and the forming of the source and drain regions 140 and 150 must all be performed after the hard data requested for coding by a user is obtained. Thus, the overall process of fabricating a mask ROM cell using BGP takes a long time to complete.

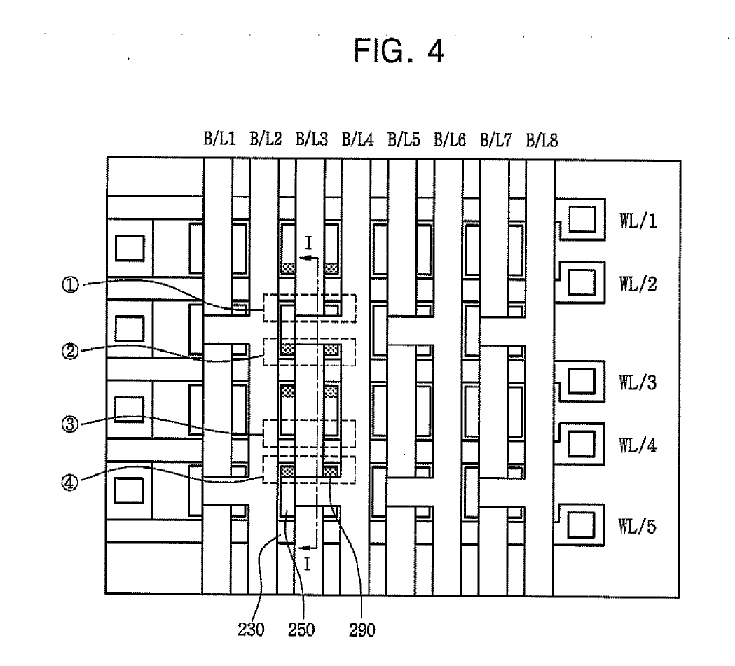

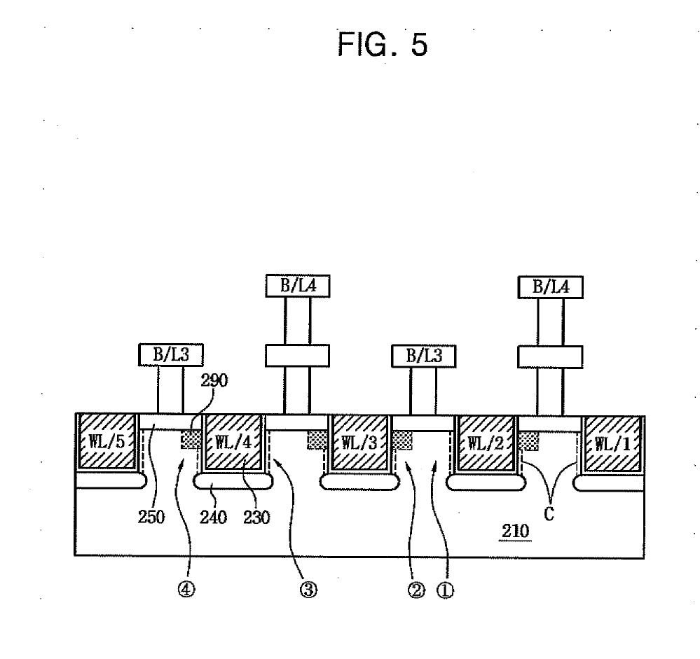

A mask ROM device according to the inventive concept will now be described with reference to FIGS. 4 and 5.

The device comprises a mask ROM cell structure including a substrate 210, gate electrodes 230 disposed at an upper portion of the substrate 210, two channels C respectively disposed along the sides of each gate electrode 230, a common source region 240 disposed in an active region of the substrate 210 under each gate electrode 230, and a common drain region 250 extending in the active region between upper portions of adjacent gate electrodes 230. Thus, the mask ROM device comprises structures each made up of a pair of cell transistors centered on one gate electrode 230.

The cell structure also includes ion implantation regions 290 each of which connects a common drain region 250 to a common source region 240. In this respect, the ion implantation region 290 forms part of a channel region C, (although it may also form part of the common drain region 250 as shown in FIG. 5). The cell transistors which are centered on the gate electrode 230 have on or off states depending on whether they include an ion implantation region 290. More specifically, a transistor which has an ion implantation region 290 as part of its channel region C is coded so as to be off, and a transistor which does not have an ion implantation region 290 as part of its channel region C is uncoded so as to be on.

The mask ROM device also includes word lines W/L, e.g., W/L1 to W/L5, integrated with the gate electrodes 230, respectively. Therefore, one word line W/L is associated with each structure made up of a pair of cell transistors because each such structure has only one gate electrode 230. That is, these two cell transistors are operated by only one word line W/L.

The mask ROM device also includes bit line B/L, e.g., bit lines B/L1 to B/L8, extending perpendicular to the word lines W/L. As described above, each gate electrode 230 is part of two cells, and two cells are operated by one word line W/L. Therefore, it is necessary to distinguish these two cells from each other. To this end, the bit lines B/L include a first column of bit lines B/L1, 3, 5 and 7 that cross over the active region, and a second column of bit lines B/L2, 4, 6 and 8 that are spaced apart from the first column and cross over the neighboring field region.

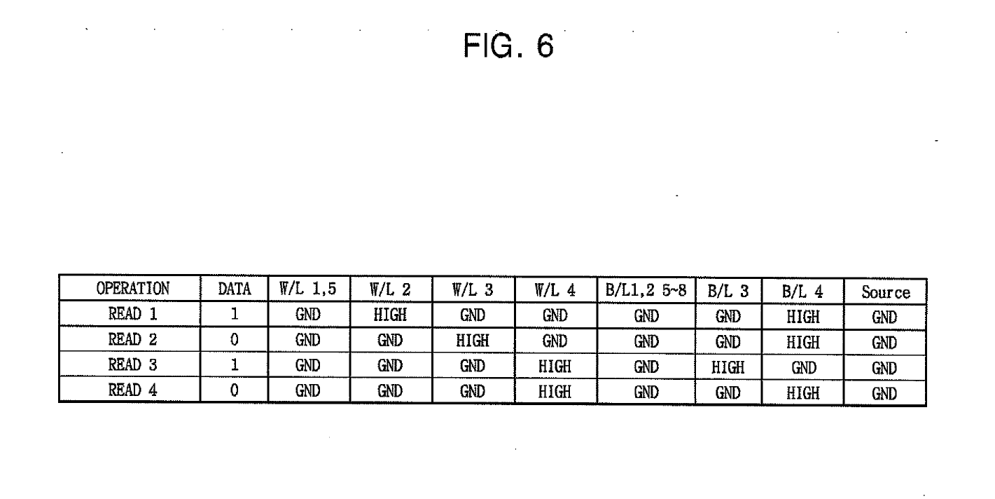

FIG. 6 illustrates the operation of the mask ROM device with respect to on cell \textcircled{1}, off cell \textcircled{2}, on cell \textcircled{3} and off cell \textcircled{4} shown in FIG. 5.

Referring to FIGS. 4 to 6, data stored in the cell \textcircled{1} is read out when a high (program) voltage is applied to the word line W/L2, a ground voltage (GND) is applied to the other word lines W/L1, 3 and 4, a high voltage is applied to the bit line B/L4, and the ground voltage (GND) is applied to the other bit lines B/L1, 2, 3, 5, 6, 7 and 8. The cell \textcircled{1} is uncoded. Therefore, current flows in the channel region C of cell \textcircled{1} when activation voltages are applied to the word line W/L2 and the bit line B/L4 and thus, the data “1” representing the status of the cell \textcircled{1} is read.

Data stored in the cell \textcircled{2} is read out when high voltages are applied to the word line W/L3 and the bit line B/L4. The cell \textcircled{2} is coded. Thus, current does not flow in the channel region C of cell \textcircled{2} even though activation voltages are applied to the word line W/L3 and bit line B/L4. Thus, the data “0” representing the status of the cell \textcircled{2} is read.

Data stored in the cell \textcircled{3} is read out when high voltages are applied to the word line W/L4 and the bit line B/L3. The cell (3) is uncoded. Therefore, current flows in the channel region C of cell \textcircled{3} when activation voltages are applied to the word line W/L4 and bit line B/L3. Thus, the data “1” representing the status of the cell \textcircled{3} is read.

Data stored in the cell \textcircled{4} is read out when high voltages are applied to the word line W/L4 and the bit line B/L4. The cell \textcircled{4} is coded. Therefore, current does not flow in the channel region C of cell \textcircled{4} even when activation voltages are applied to the word line W/L4 and bit line B/L4. Thus, the data of “0” representing the status of the cell \textcircled{4} is read.

As is clear from FIG. 5, the cells \textcircled{3} and \textcircled{4} share the same gate electrode 230. Therefore, a program voltage is applied to the cells \textcircled{3} and \textcircled{4} through the same word line (W/L4). However, the on cell \textcircled{3} having the non-programmed channel region C and the off cell \textcircled{4} having the programmed channel region C have different threshold voltages. Therefore, the data stored in the cells \textcircled{3} and \textcircled{4} are expressed differently as “1” and “0”, respectively. Meanwhile, the on cell \textcircled{3} and the off cell \textcircled{4} which share the same gate electrode 230 may selectively receive a high and a ground voltage through the bit lines B/L3 and 4.

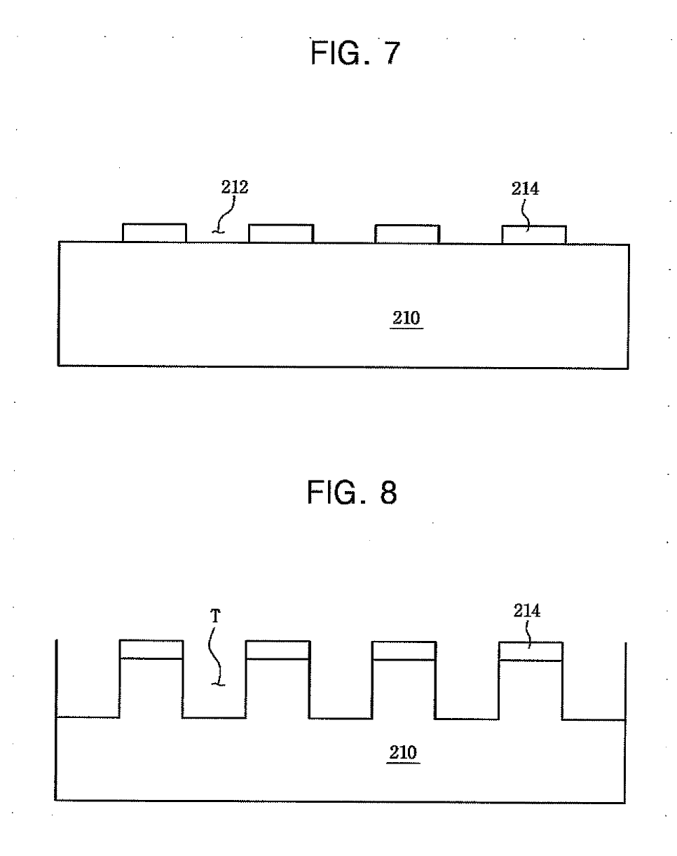

Hereinafter, a method of fabricating a mask ROM cell structure according to the inventive concept will be described with reference to FIGS. 7-15.

Referring to FIG. 7, a photoresist is applied to a semiconductor substrate 210, and the resulting layer of photoresist is exposed and developed to form a photoresist pattern 214 having openings 212 therethrough at predetermined intervals. The openings 212 thus expose the semiconductor substrate 210 at regular intervals. As shown in FIG. 8, the semiconductor substrate 210 is etched using the photoresist pattern 214 as an etch mask, thereby forming trenches T. The cross section of the trench T may have the shape of a tetragon or inverted trapezoid. Also, each of the trenches T thus has a predetermined width, and adjacent ones of the trenches T are separated by segments of the active region, respectively.

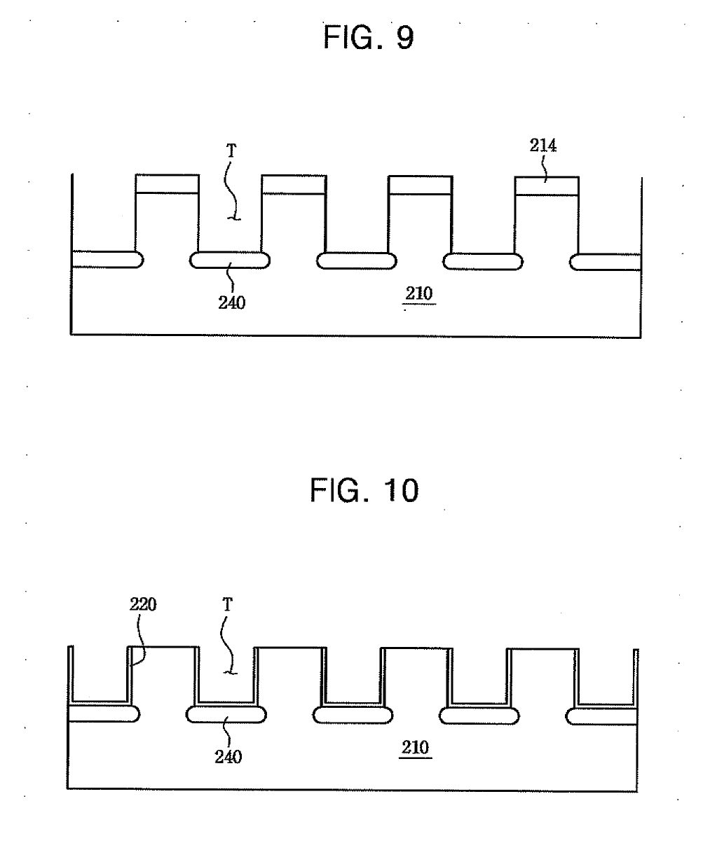

As shown in FIG. 9, a common source region 240 is formed in the substrate 210 at the bottom of the trench T. The common source region 240 is formed by implanting impurity ions into the substrate 210 using the mask 214 as an ion implantation mask. In this example in which the method is carried out to form NMOS transistors, the ion implantation is performed using phosphorous (P) or arsenic (As) with an energy of about 100 KeV.

Subsequently, as shown in FIG. 10, a gate oxide layer 220 is formed on the surfaces of the substrate 210 which delimit the trench T. The gate oxide layer 220 may be formed of SiO₂ by a thermal process or a wet oxidation process. The gate oxide layer 220 serves to insulate the gate electrode 230, which will be buried in the trench T, from the channels C which will be formed on the sides of the trench T, and to minimize parasitic capacitance between the gate electrode 230 and the common source region 240.

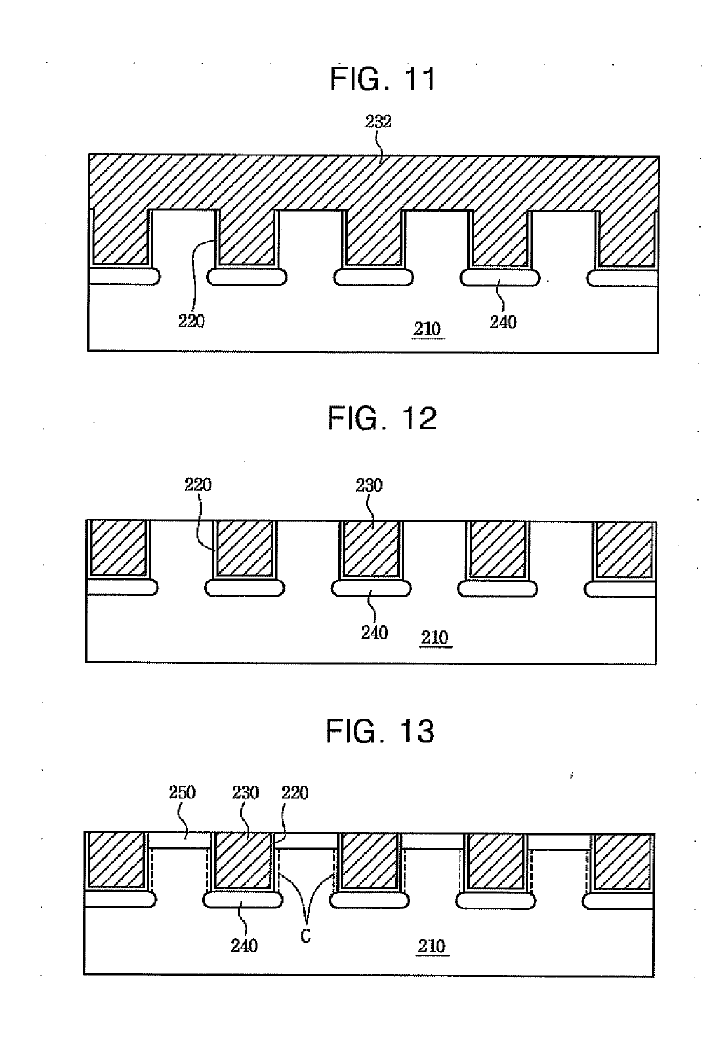

As shown in FIG. 11, the trench T is overfilled with polysilicon 232. The polysilicon 232 may be formed by depositing doped silicon on the substrate 210 using LPCVD, or by depositing undoped silicon on the substrate 210 and then doping the silicon using ion implantation. However, the material used to fill the trenches T is not limited to doped polysilicon 232. Rather, other materials that may be used instead include metals, metal silicides or combinations thereof. That is, polysilicon 232 is only an example of the material that can be used for filling the trenches T.

As shown in FIG. 12, the resulting layer of polysilicon 232 is dry etched to form the gate electrodes 230. At this time, the upper surfaces of the gate electrodes 230 may be at a level equal to or slightly beneath the level of the upper surface of the semiconductor substrate 210.

As shown in FIG. 13, n-type impurity ions are implanted into the active region of the semiconductor substrate using the gate electrodes 230 as a mask, thereby forming drain regions 250. At this time, the channel regions C are formed between the common source regions 240 and the common drain regions 250.

Also, at this time, none of the transistors are coded. Therefore, if an activation or program voltage were to be applied to the gate electrode 230 of any of the transistors, current would flows from the source region 240 to the drain region 250 via the channel region C of the transistor. Thus, the state of the transistor would be read as storing data “1”.

According to the inventive concept, a coding process is performed to adjust the threshold voltage of selected ones of the transistors. The coding of a transistor in this case increases its threshold voltage such that current will not flow from the source region 240 to the drain region 250 via the channel region C of the transistor even when an activation or program voltage is applied to the gate electrode 230 of the transistor. Thus, the data of the transistor will be read out as “0” from a coded transistor even when an activation or program voltage is applied to the gate electrode 230 of the transistor.

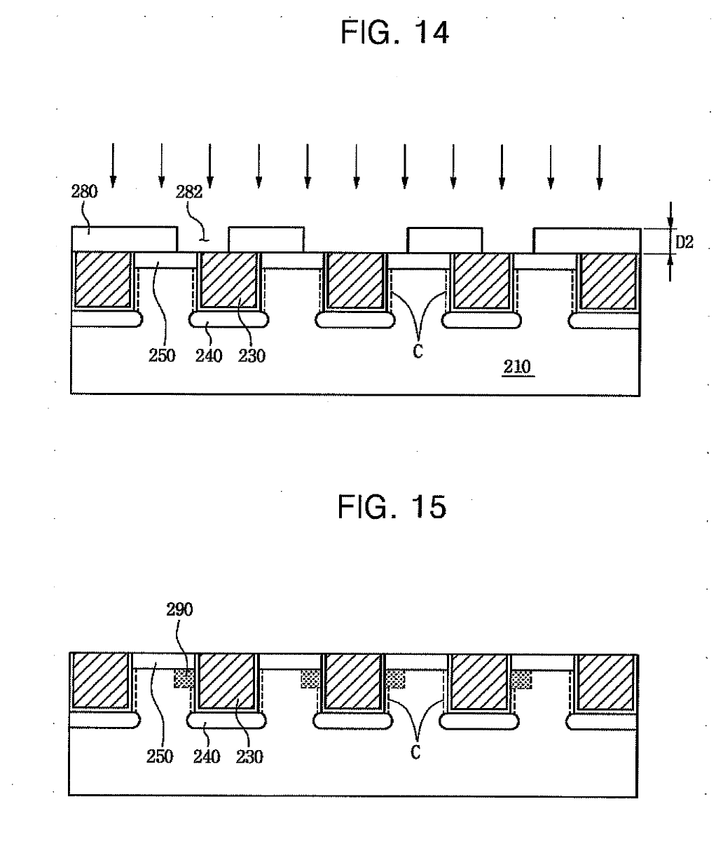

FIG. 14 shows an example of a coding process carried out according to a user's specifications. As shown in FIG. 14, a photoresist is patterned to form a mask 280 on the substrate 210. The mask 280 has openings 282 each of which exposes the active region and the gate electrode 230 of a transistor to be coded. More specifically, each opening 282 exposes a channel region C and the gate electrode 230 along which the channel region C extends, but for each transistor the opening 282 does not expose more than half (widthwise) of the gate electrode 230, nor does the opening 282 expose more than half (widthwise) of the active region in which the channel region C is formed.

The exposed active region is then doped by performing an ion implantation process using the mask 280 as an ion implantation mask. As a result, ions are implanted into the channel region C through a drain region 250 that is exposed instead of through a gate electrode 230. Thus, ion implantation regions 290 are formed as extending from the surface of the active region in a vertically downward direction. Each ion implantation region 290 is wider than the channel region C in which it is formed. Moreover, the ion implantation region 290 is no longer than about 30% of the length of the original channel region C (in the vertical direction) in which it is formed. Nonetheless, the threshold voltage is increased between the drain region 250 and the source region 240 due to the ion implantation region 290.

The implanting of ions using the mask 280 for coding applies to the forming of either NMOS or PMOS transistors. In the case of forming NMOS transistors as in the present example, the ion implantation regions 290 are formed by implanting p-type ions. However, in an alternative example in which PMOS transistors are formed, the ion implantation regions are formed by implanting n-type ions.

As shown in FIG. 15, the mask 280 for coding is then removed.

In the method shown in FIGS. 2 and 3, the thickness D1 of the photoresist pattern 180 must be kept in a range from 7000 to 9000 Å to facilitate the photolithography process considering the fineness of the pattern of transistors. Also, in the case of implanting boron ions, the ion implantation energy must be maintained in a range from 60 to 120 KeV in an attempt to propel the ions through the gate electrodes 130 without damaging the lattice structure of the gate electrodes 130 or separating the gate electrodes 130 from the gate oxide layer 120.

On the other hand, according to one aspect of the inventive concept, a shallow ion implantation process is used to code the transistors. In an example of this process shown in FIG. 14, the ion implantation energy is in a range of from 20 to 30 Key, and the thickness D2 of the ion-implantation mask 280 is in a range of from 4000 to 5000 Å. Accordingly, coded transistors which meet a user's specifications can be formed without high ion implantation energy, the mask 280 used in the coding does not have to be thick, and hence, the method facilitates the forming of a fine pattern of coded transistors.

Furthermore, in trench-type cell transistors embodied according to the inventive concept, the buried gate electrodes overlie the source regions. Thus, the transistors can be half of the size of planar cell transistors. More specifically, the footprint of a cell transistor embodied according to the inventive concept can be dramatically reduced because two cell transistors share one gate electrode.

Finally, embodiments of the inventive concept have been described herein in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiments described above but by the following claims.

1. A method of fabricating a mask read-only memory (ROM) cell structure, comprising:
providing a semiconductor substrate having an active region;
forming on the semiconductor substrate a photoresist pattern that exposes the active region of the semiconductor substrate at regular intervals;
etching the semiconductor substrate using the photoresist pattern as a mask to form trenches in the active region of the semiconductor substrate, wherein the trenches each have a bottom and opposite sides, and the trenches are separated from one another by segments of the active region;
forming common source regions along the bottoms of the trenches, respectively, comprising implanting impurity ions into surfaces of the substrate which delimit the bottoms of the trenches;
forming a gate oxide layer along the bottom and sides of each of the trenches;
overfilling the trenches with gate electrode material;
planarizing the gate electrode material to form gate electrodes in the trenches, respectively;
forming common drain regions along upper portions of the segments of the active region that separate the trenches from each other, respectively, and channel regions which extend to the common source regions vertically along the sides of the segments, wherein the forming of the common drain regions and the channel regions comprises implanting impurity ions into the active region of the substrate; and
performing a coding process resulting in the threshold voltages of at least one of the channel regions being differentiated from the threshold voltage of at least one other of the channel regions.

2. The method according to claim 1, wherein the overfilling of the trenches with gate electrode material comprises overfilling the trenches with polysilicon, and the planarizing of the gate electrode material comprises dry etching the polysilicon until the upper surface thereof is no higher than the upper surface of the active region.

3. The method according to claim 1, wherein the forming of the common source regions comprises using the photoresist pattern as a mask during the implanting of impurity ions into surfaces of the substrate which delimit the bottoms of the trenches, and the forming of the common drain regions comprises implanting impurity ions into the active region of the substrate using the gate electrodes as a mask.

4. The method according to claim 1, wherein the coding process comprises forming on the substrate a coding mask having at least one opening that exposes the active region and implanting ions into the active region using the coding mask as an ion implantation mask to form at least one ion implantation region.

5. The method according to claim 4, wherein the coding mask is formed to a thickness of about 4000 to about 5000 Å.

6. The method according to claim 4, wherein the implanting of ions in the coding process is performed at an energy level of from about 20 to about 30 KeV.

7. The method according to claim 4, wherein the coding process is performed after the gate electrodes and channel regions are formed, and one said opening of the coding mask exposes one of the channel regions, no more than a width-wise half of the gate electrode disposed to one side of the exposed channel region, and no more than a width-wise half of the segment of the active region disposed on the other side of the exposed channel region.

8. The method according to claim 4, wherein the coding process is performed such that the ion implantation region is formed along the channel region over a distance of less than 30% of the length of the channel region between the common source and drain regions, and such that the ion implantation region is wider than the original channel region in which it is formed.

9-20. (canceled)

21. A method of fabricating a mask read-only memory (ROM) cell, comprising:
forming trenches in an active region of a substrate at regular intervals;
forming common source regions along a bottom of each of the trenches;
forming gate oxide layers along the bottom and opposite sides of each of the trenches;
forming gate electrodes in each of the trenches;
forming common drain regions along upper portions of the active region between the gate electrodes;
forming vertical channel regions which extend vertically between the common source regions and the common drain regions; and
forming selectively ion implantation regions in the vertical channel regions.

22. The method according to claim 21, wherein forming of trenches comprises:
applying a photoresist to the substrate;
exposing and developing the photoresist to form photoresist patterns wherein the photoresist patterns have openings therethrough at regular intervals; and
etching the substrate using the photoresist patterns as an etch mask.

23. The method according to claim 22, wherein forming of common source regions comprises:
implanting impurity ions into the bottom of each of the trenches using the photoresist patterns as an implant mask.

24. The method according to claim 21, wherein forming of the gate electrodes comprises:
overfilling the trenches with polysilicon; and
etching the polysilicon until the upper surface thereof is no higher than the upper surface of the active region.

25. The method according to claim 24, wherein forming of the common drain regions comprises:
implanting impurity ions into the upper portions of the active region using the gate electrodes as a implant mask.

26. The method according to claim 21, wherein two vertical channel regions form on opposite sides of one gate electrode, and one gate electrode is disposed between a pair of cell transistors, and the cell transistors disposed on opposite sides of the gate electrode are selectively turned on or off depending on whether the implantation regions is formed in the vertical channel regions or not.

27. The method according to claim 21, wherein the ion implantation regions is also formed in the common drain regions at the same time.

28. The method according to claim 21, wherein the ion implantation regions is no longer than about 30% of the length of the vertical channel region.

29. The method according to claim 21, wherein the ion implantation regions is wider than the channel region.
